(19) United States
(12) Patent Application Publication
(10) Pub. No.: US 2010/0140578 A1
(43) Pub. Date: Jun. 10, 2010

(54) NON VOLATILE MEMORY CELLS INCLUDING A COMPOSITE SOLID ELECTROLYTE LAYER

(75) Inventors: Wei Tian, Bloomington, MN (US); Ming Sun, Eden Prairie, MN (US); Michael Xuefei Tang, Bloomington, MN (US); Dimitar V. Dimitrov, Edina, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, Scotts Valley, CA (US)

(21) Appl. No.: 12/425,071

(22) Filed: Apr. 16, 2009

Related U.S. Application Data
(60) Provisional application No. 61/120,195, filed on Dec. 5, 2008.

(51) Int. Cl. H01L 47/00; B05D 5/12; C23C 14/34

(52) U.S. Cl. 257/2; 427/58; 204/192.15; 427/126.3; 427/126.1; 257/E47.001

(57) ABSTRACT

Programmable metallization cells (PMC) that include a first electrode; a solid electrolyte layer including clusters of high ion conductive material dispersed in a low ion conductive material; and a second electrode, wherein either the first electrode or the second electrode is an active electrode, and wherein the solid electrolyte layer is disposed between the first electrode and the second electrode. Methods of forming them are also included herein.

### PRIORITY

This application claims priority to U.S. Provisional Application No. 61/120195, entitled “NANOCOMPOSITE OXIDE SOLID ELECTROLYTES FOR PROGRAMMABLE METALLIZATION CELLS” filed on Dec. 5, 2008, the disclosure of which is incorporated herein by reference.

### BACKGROUND

The programmable metallization cell (PMC) and resistive random access memory (RRAM) cell are new types of memory that are candidates to eventually replace flash memory. Both PMC and RRAM can offer the benefits of longer lifetimes, lower power and better memory density. As PMC and RRAM are still being developed, there remains a need for novel or advantageous PMCs and RRAMs for use in memory applications that can exhibit better data retention while not significantly sacrificing switching speed.

### BRIEF SUMMARY

Disclosed herein is a programmable metallization cell (PMC) that includes a first electrode; a solid electrolyte layer that includes clusters of high ion conductive material dispersed in a low ion conductive material; and a second electrode, wherein the solid electrolyte layer is disposed between the first electrode and the second electrode.

Disclosed herein is a method of forming a PMC that includes forming a first electrode; forming a solid electrolyte layer, the solid electrolyte layer including a low ion conductive material and a high ion conductive material and forming a second electrode.

Also disclosed herein are nonvolatile memory units that include resistive sense memory cells (RMS) that include a first electrode; a solid electrolyte layer including clusters of high ion conductive material dispersed in a low ion conductive material; and a second electrode, wherein the solid electrolyte layer is disposed between the first electrode and the second electrode; at least one word line; and at least one bit line, wherein the word line is orthogonal to the bit line and the RMS is operatively coupled to the word line and the bit line.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIG. 1A is a schematic side view diagram of an illustrative programmable metallization cell (PMC) in a low resistance state; FIG. 1B is schematic side view diagram of the illustrative PMC in a high resistance state;

FIG. 2A is a schematic side view diagram of a PMC that includes a disclosed solid electrolyte layer in a high resistance state; FIG. 2B is schematic side view diagram of the illustrative PMC in a low resistance state;

FIG. 3 is a flowchart illustrating an exemplary method for forming a PMC;

FIGS. 4A through 4D are schematic diagrams illustrating a PMC at various stages of formation;

FIG. 5 is a schematic diagram of an illustrative programmable metallization memory unit including a semiconductor transistor; and

FIG. 6 is a schematic perspective view of a memory array including PMCs as disclosed herein

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

Spatially related terms, including but not limited to, “lower”, “upper”, “beneath”, “below”, “above”, and “on top”, if used herein, are utilized for ease of description to describe spatial relationships of an element(s) to another. Such spatially related terms encompass different orientations of the device in use or operation in addition to the particular orientations depicted in the figures and described herein. For example, if a cell depicted in the figures is turned over or flipped over, portions previously described as below or beneath other elements would then be above those other elements.

As used herein, when an element, component or layer for example is described as being “on” “connected to”, “coupled with” or “in contact with” another element, component or layer, it can be directly on, directly connected to, directly coupled with, in direct contact with, or intervening elements, components or layers may be on, connected, coupled or in contact with the particular element, component or layer, for example. When an element, component or layer for example is referred to as begin “directly on”, “directly connected to”, “directly coupled with”, or “directly in contact with” another element, there are no intervening elements, components or layers for example.

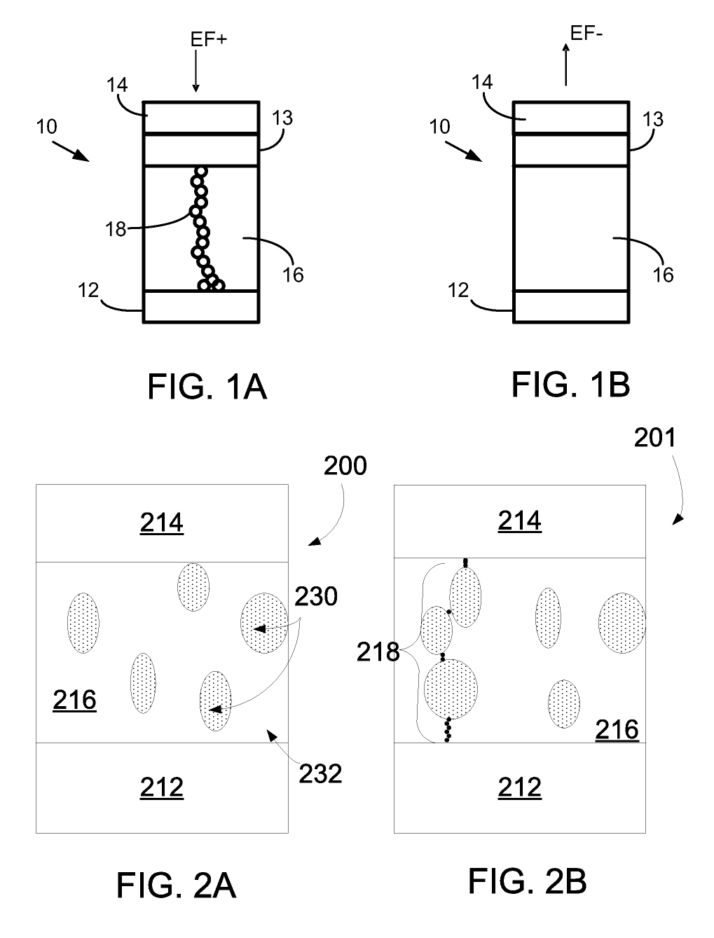

Disclosed herein are resistive sense memory (RSM) cells. A RSM cell is a memory cell having a changeable resistance that affords data storage using different resistance states of the RSM cell. An exemplary type of a RSM cell is a programmable metallization cell (PMC). A PMC utilizes a solid electrolyte layer; at least two electrodes (e.g., an anode and a cathode) with the solid electrolyte layer positioned between the electrodes and in some embodiments a sink layer. FIG. 1A is a cross-sectional schematic diagram of an illustrative PMC 10 that includes a first electrode 12, a second electrode 14, a solid electrolyte layer 16, and optionally a sink layer 13. Solid electrolyte layer 16 is positioned between the first electrode 12 and the second electrode 14. FIG. 1A depicts the sink layer 13 positioned between the second electrode 14 and the solid electrolyte layer 16. In embodiments (not depicted herein), the sink layer can alternatively be positioned between the first electrode and the solid electrolyte layer.

When a voltage is applied across the electrodes, conducting filaments grow from the cathode through the solid electrolyte layer towards the anode. In FIG. 1A, application of an electric field EF+ across the second electrode 14 allows cations from the sink layer 13 to migrate toward the first electrode 12, forming conducting filaments 18 within the solid electrolyte layer 16. The presence of conducting filaments 18 within the solid electrolyte layer 16 reduces the electrical resistance between the first electrode 12 and the second electrode 14 and gives rise to the low resistance state of the PMC 10.

When an electric field of the opposite polarity is applied across the electrodes, the conducting filaments dissolve and the conducing paths are disrupted, providing the PMC with a high resistance state. FIG. 1B illustrates this, application of electric field EF− (a field having the opposite polarity of EF+) to the PMC 10 ionizes the conducting filaments 18 and moves the ions back to the sink layer 13 or one of electrodes 14 or 12, and gives rise to the high resistance state of the PMC 10. As seen here the low resistance state and the high resistance state are switchable with an applied electric field and can be used to store the memory bit “1” and “0”.

Reading the PMC 10 simply requires application of a small voltage across the PMC 10. If the conducting filaments 18 are present in the PMC 10, the resistance will be low, leading to a higher current, which can be read as a “1”. If there are no conducting filaments 18 present in the PMC 10, the resistance is higher, leading to a lower current, which can be read as a “0”. It will also be understood that “1” can be associated with the high resistance and “0” can be associated with the low resistance.

The first electrode 12 can generally be a conductive material, such as a metal. The first electrode can also be referred to as a bottom electrode. The first electrode can be made of any conductive material, including but not limited to those including tungsten (W) or a noble metal such as gold (Au), platinum (Pt), palladium (Pd), rhodium (Rh), copper (Cu), Nickel (Ni), Silver (Ag), Cobalt (Co) or Iron (Fe). In embodiments, the first electrode can have a thickness from about 50 Å to about 5000 Å.

The second electrode 14 can also generally be a conductive material, such as a metal. In an embodiment, the second electrode can also be referred to as a top electrode. The second electrode can be made of any conductive material, including but not limited to, tungsten (W) or a noble metal such as gold (Au), platinum (Pt), palladium (Pd) or rhodium (Rh). In embodiments, the second electrode can have a thickness from about 50 Å to about 5000 Å.

In embodiments where the sink layer 13 is positioned adjacent the second electrode 14 (the configuration depicted in the figures), the second electrode is considered the active electrode. In embodiments where the sink layer is positioned adjacent the first electrode (this configuration is not depicted herein), the first electrode will be considered the active electrode. The material for the sink layer 13 is selected based on its ion diffusivity. In embodiments, sink layer 13 is electrochemically active, made of an oxidizable material, for example, silver (Ag), copper (Cu), tantalum (Ta), titanium (Ti), etc. In some embodiments, the sink layer 13 is positioned directly adjacent the second electrode 14 (or alternatively the first electrode), without intervening layers. Sink layer 13 often has a thickness of about 2-50 nm.

In embodiments, the solid electrolyte layer 16 can be formed of any useful material that provides for the formation of conducting filaments 18 within the solid electrolyte layer 16 and extension between the first electrode 12 and the second electrode 14 upon application of an electric field EF+.

Generally, the solid electrolyte layer 16 includes at least two different materials. In embodiments, the solid electrolyte layer 16 includes a high ion conductive material and a low ion conductive material. In embodiments, the high ion conductive material and the low ion conductivity material are chosen so that upon application of a positive electric field to the second electrode, ions will find the shortest path through the solid electrolyte layer that preferentially spans the high ion conductivity material.

In embodiments, the high ion conductive material has an ionic conductivity that is at least an order of magnitude higher than the ionic conductivity of the low ion conductive material. In embodiments, the high ion conductive material is one that has an ionic conductivity of at least about 0.1/Ωcm. In embodiments, the high ion conductive material is one that has an ionic conductivity from about 0.1/Ωcm to about 1/Ωcm. In embodiments, the low ion conductive material is one that has an ionic conductivity of at least about 0.01/Ωcm. In embodiments, the low ion conductive material is one that has an ionic conductivity from about 0.01/Ωcm to about 0.1/Ωcm. In embodiments, the high ion conductive material is one that has an ionic conductivity from about 0.1/Ωcm to about 1/Ωcm and the low ion conductive material is one that has an ionic conductivity from about 0.01/Ωcm to about 0.1/Ωcm.

Materials that can be utilized as high ion conductive materials in the solid electrolyte layer 16 include, but are not limited to materials such as silver sulfide (Ag₂S), silver iodide (AgI), copper sulfide (Cu₂S), copper iodide (CuI), copper tellurium (CuTe), silver selenide (Ag₂Se), silver tellurium (AgTe), or combinations thereof.

Materials that can be utilized as low ion conductive materials in the solid electrolyte layer 16 include, but are not limited to materials such as tungsten oxide (WOₓ), silicon dioxide (SiO₂), and gadolinium oxide (Gd₂O₃), germanium sulfide (Ge₂S), or combinations thereof

The solid electrolyte layer generally comprises both the low ion conductive material and the high ion conductive material and can, but need not be a mixture of the two components. In embodiments where the solid electrolyte layer is a mixture, the mixture can be homogeneous, mostly homogeneous, somewhat homogeneous, somewhat heterogeneous, mostly heterogeneous, heterogeneous, or any characterization in between. The solid electrolyte layer can, but need not have portions with a higher amount of one component and portions with a higher amount of the other component. The solid electrolyte layer could also be considered as a layer of one component with inclusions of the other component.

Any useful amounts of high ion conductive material and low ion conductive material can be included in the solid electrolyte layer 16. In embodiments, there is more low ion conductive material (by volume) than high ion conductive material. In embodiments, the solid electrolyte layer 16 can include from about 99% to about 60% (by volume) low ion conductive material and from about 1% to about 40% (by volume) high conductive material.

FIG. 2A depicts an exemplary PMC 200. This exemplary PMC 200 includes a first electrode 212, a second electrode 214, and a solid electrolyte layer 216. In some embodiments, a sink layer (not shown) could be included adjacent to first electrode 212 or second electrode 214. The solid electrolyte layer 216 can generally have a structure that includes clusters or areas of the high ion conductive material interspersed in the low ion conductive material. The clusters or areas of high ion conductive material, which are depicted schematically as high ionic conductivity clusters 230 can be dispersed in any fashion (i.e. random, somewhat random, somewhat uniform, uniform or any characterization in between) within the low ionic conductivity areas 232. In an embodiment, the low ionic conductivity areas 232 can generally form a continuous phase in which the high ionic conductivity clusters 230 are dispersed. The high ionic conductivity clusters 230 can have any shape, whether regular or irregular. In embodiments, the high ionic conductivity clusters 230 can be described as spheres, even though they may not be perfect spheres, and as such can be described by there average diameters. Other regular volumes, such as cubes for example, can also be utilized to describe the volumes of the high ionic conductivity clusters 230.

In embodiments, the solid electrolyte layer 216 has a thickness in the nanometer (nm) range. In embodiments, the solid electrolyte layer 216 has a thickness in the range of tens of nanometers to hundreds of nanometers. In embodiments, the solid electrolyte layer 216 has a thickness from about 3 nm to about 300 nm. In embodiments, the solid electrolyte layer 216 has a thickness from about 20 nm to about 200 nm. In embodiments, the high ionic conductivity clusters 230 can have diameters (even though some or all of the high ionic conductivity clusters 230 may not be perfect spheres) in the nanometer range. In embodiments, the high ionic conductivity clusters 230 can have diameters in the range of a few nanometers to tens of nanometers. In embodiments, the high ionic conductivity clusters 230 can have diameters from about 1 nm to about 50 nm. In embodiments, the high ionic conductivity clusters 230 can have diameters from about 2 nm to about 30 nm. In embodiments, the high ionic conductivity clusters 230 can have diameters from about 3 nm to about 25 nm.

FIG. 2B depicts a PMC 201 after a voltage has been applied across the electrodes and a conducting filament has grown from the second electrode 214 or optionally a sink layer to the first electrode 212. The conducting filament 218 forms along a path from the sink layer or second electrode 214 to the first electrode 212 that utilizes the high ion conductivity clusters 230. The path of the conducting filament 218 has an effective length through the solid electrolyte layer 216. The effective length of the conducting filament in the total length of the low ion conductivity material 232 that the conductive filament 218 must cross. As seen in FIG. 2B, the presence of the high ion conductivity clusters 230 decreases the effective length of the conductive filament, when compared to the solid electrolyte layer 216 without the high ion conductivity clusters 230 present.

As seen in the exemplary depiction in FIG. 2B, solid electrolyte layers as described herein offer an advantage of reducing the effective length of the conducting filament necessary to obtain the low resistance state. This decreases the time necessary for switching the PMC from the high to low resistance state. The high ionic conductive clusters can also decrease the amount of reduced metal atoms that have to be oxidized when the conducting filaments are broken by the opposing voltage. This can have the effect of reducing the time necessary to switch from the low resistance state to the high resistance state.

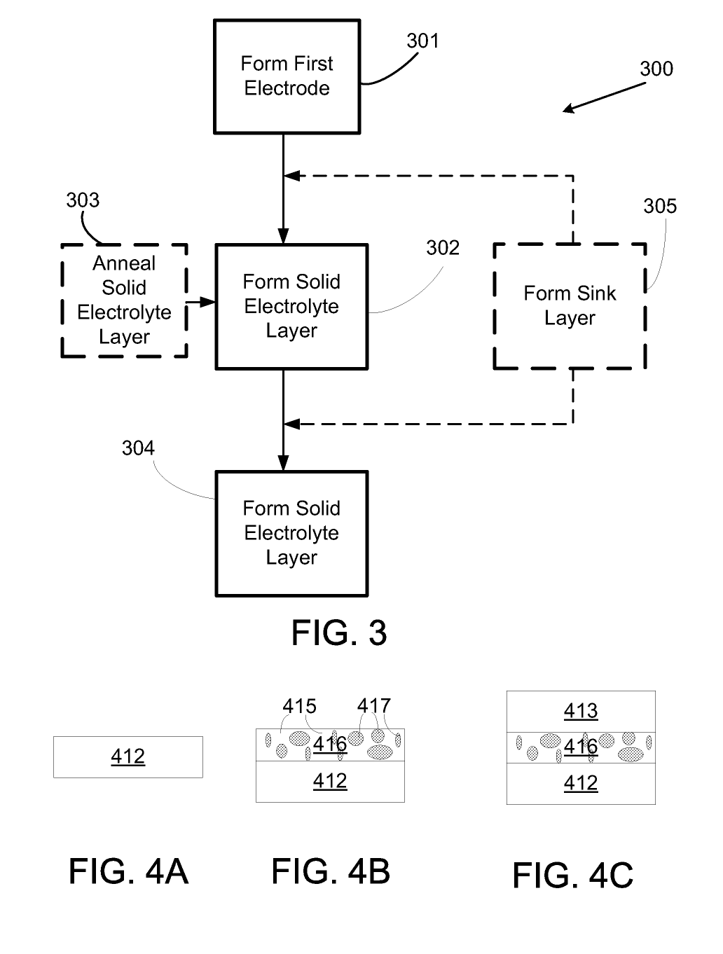

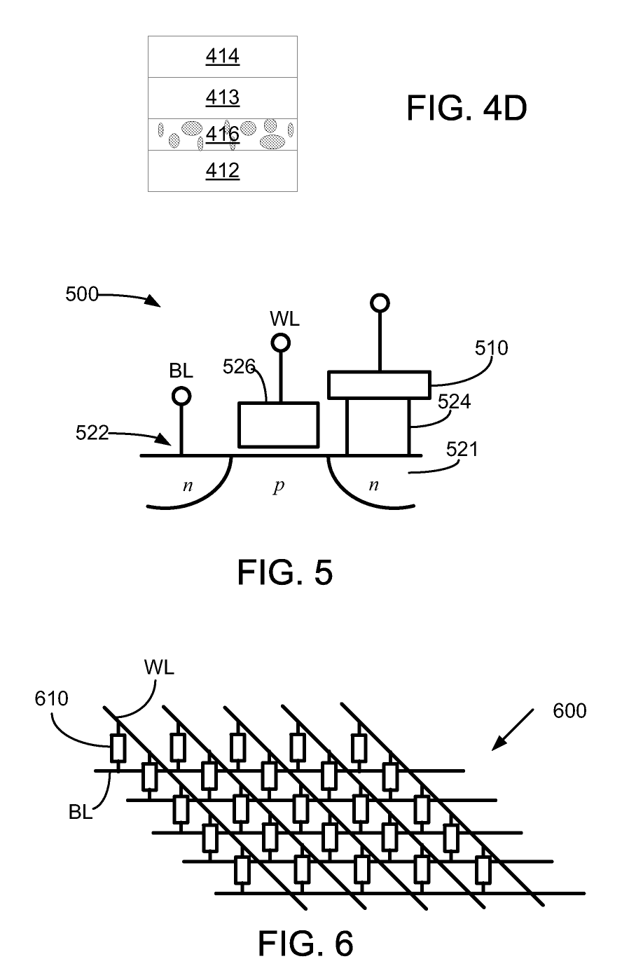

FIG. 3 depicts an exemplary method of fabricating a disclosed PMC. Although the method depicted in FIG. 3 is depicted as having a certain order, the steps discussed herein can generally be carried out in any order, other steps (both discussed herein and not discussed herein) can be added, and the order of any steps can be rearranged. The exemplary method shown in FIG. 3 includes as a first step, step 301 forming a first electrode. The first electrode can be made of materials as discussed above (W, Au, Pt, Pd, Rh, Cu, Ni, Ag, Co, or Fe) and can be formed using fabrication methods such as physical vapor deposition (PVD), chemical vapor deposition (CVD), electrochemical deposition (ECD), molecular beam epitaxy (MBE), metalorganic chemical vapor deposition (MOCVD), and atomic layer deposition (ALD). The first electrode can be, but need not be formed on a substrate. The substrate, if utilized, can include silicon, a mixture of silicon and germanium, and other similar materials. FIG. 4A illustrates an exemplary article after completion of this first step, FIG.4A does not depict an optional substrate, but does show the first electrode 412.

The next step in the depicted method includes step 302, forming the solid electrolyte layer. In embodiments, the step of forming the solid electrolyte layer can be accomplished by depositing the low ion conductive material and the high ion conductive material, thereby forming a deposited two component layer. In embodiments, a method of depositing the low and high ion conductive materials can include two different sources, one for each of the components. Deposition of two different components utilizing sputtering processes can be referred to as co-sputtering. In embodiments, a deposition method that can be utilized can utilize a single source that includes each of the components. Multiple sources that either provide atomic components of the two components or compound sources of one or more of the components can also be utilized. Exemplary methods of depositing the low and high ion conductive materials include, but are not limited to, sputter deposition methods such as radio frequency (RF) sputtering, ion-beam sputtering, reactive sputtering, ion-assisted deposition, high-target-utilization sputtering, high power impulse magnetron sputtering (HIPIMS) and other deposition methods such as PVD, CVD, ECD, MBE, MOCVD, and ALD. The amounts of the two components in the deposited two component layer can be controlled for example, by the power of the sputtering as well as other process parameters. FIG. 4B illustrates an exemplary article after completion of step 302, showing the first electrode 412 and the solid electrolyte layer 416.

In some embodiments, an optional step, step 303 annealing the deposited materials can be carried out. Generally, annealing can cause at least one of the two components in the solid electrolyte layer to diffuse or migrate, ultimately leading to portions of the deposited two component layer that have a higher concentration of the low ion conductive material and portions that have a higher concentration of the high ion conductive material. Although the step of annealing is not necessary, it can lead to a solid electrolyte layer that more concentrated areas of high ion conductivity material, which can lead to a device having faster switching times. The conditions of annealing can depend at least in part on the identities of the two components, the amounts of the two components, the melting points of the two components, the lattice constants of the two components, the diffusion coefficients of the two components, or combinations thereof. Generally, the conditions utilized for annealing cause at least one of the components to migrate and should not detrimentally affect either of the components.

Step 305, forming the sink layer or making one of the electrodes the active electrode can be carried out after step 301, formation of the first electrode or after step 302, formation of the solid electrolyte layer. In embodiments where the sink layer is positioned between the first electrode and the solid electrolyte layer, step 305 can be carried out before step 302, formation of the solid electrolyte layer. In embodiments where the sink layer is positioned between the second electrode and the solid electrolyte layer, step 305 can be carried out after step 302, formation of the solid electrolyte layer. The sink layer can be made of conductive materials as discussed above (Ag, Cu, Ta, and Ti for example) and can be formed using fabrication methods such as PVD, CVD, ECE, MBE, MOCVD and ALD. Other methods of making one of the electrodes the active electrode besides depositing a sink layer can be conducted here.

The next step, step 304 is to form the second electrode. The second electrode can be made of materials as discussed above (W, Au, Pt, Pd, or Rh) and can be formed using fabrication methods such as PVD, CVD, ECD, MBE, MOCVD, and ALD. FIG. 4D illustrates an exemplary article after completion of step 304, showing the first electrode 412, the solid electrolyte layer 416, the optional sink layer 413, and the second electrode 414.

FIG. 5 is a schematic diagram of an illustrative programmable metallization memory unit 500 including a semiconductor transistor 522. Memory unit 500 includes a PMC 510, as described herein, electrically coupled to semiconductor transistor 522 via an electrically conducting element 524. Transistor 522 includes a semiconductor substrate 521 having doped regions (e.g., illustrated as n-doped regions) and a channel region (e.g., illustrated as a p-doped channel region) between the doped regions. Transistor 522 includes a gate 526 that is electrically coupled to a word line WL to allow selection and current to flow from a bit line BL to PMC 510. Arrays of memory units 500 can be formed on a semiconductor substrate utilizing semiconductor fabrication techniques. FIG. 6 is a schematic diagram of an illustrative array 630 of PMCs. Memory array 630 includes a plurality of word lines WL and a plurality of bit lines BL forming a cross-point array. At each cross-point a PMC 510, as described herein, can be electrically coupled to word line WL and bit line BL.

Programmable metallization cells (PMCs) as disclosed herein can be included in stand alone devices or can be integrated or embedded in devices that utilize the PMCs including but not limited to microprocessors (e.g., computer systems such as a PC e.g., a notebook computer or a desktop computer or a server) microcontrollers, dedicated machines such as cameras, and video or audio playback devices.

Thus, embodiments of NON VOLATILE MEMORY CELLS INCLUDING A COMPOSITE SOLID ELECTROLYTE LAYER are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present disclosure is limited only by the claims that follow.

What is claimed is:

1. A programmable metallization cell (PMC) comprising:
a first electrode;
a solid electrolyte layer comprising clusters of high ion conductive material dispersed in a low ion conductive material; and
a second electrode,
wherein either the first electrode or the second electrode is an active electrode, and
wherein the solid electrolyte layer is disposed between the first electrode and the second electrode.

2. The PMC according to claim 1, wherein the high ion conductive material has an ionic conductivity from about 0.1/Ωcm to about 1/Ωcm.

3. The PMC according to claim 1, wherein the low ion conductive material has an ionic conductivity from about 0.01/Ωcm to about 0.1/Ωcm.

4. The PMC according to claim 1, wherein the solid electrolyte layer has a thickness from about 3 nm to about 300 nm and the clusters of high ion conductive material have diameters from about 1 nm to about 50 nm.

5. The PMC according to claim 1, wherein the low ion conductive material is selected from the group consisting of: silicon dioxide (SiO₂), gadolinium oxide (Gd₂O₃), tungsten oxide (WOₓ), germanium sulfide (Ge₂S), and combinations thereof.

6. The PMC according to claim 1, wherein the high ion conductive material is selected from the group consisting of: silver sulfide (Ag₂S), silver iodide (AgI), copper sulfide (Cu₂S), copper iodide (CuI), copper tellurium (CuTe), silver selenide (Ag₂Se), silver tellurium (AgTe), and combinations thereof.

7. The PMC according to claim 1, wherein the low ion conductive material and the high ion conductive material are codeposited on the first electrode layer.

8. The PMC according to claim 7, wherein the codeposited layer is annealed to form the clusters of high ion conductive material in the low ion conductive material.

9. The PMC according to claim 1, wherein a sink layer is disposed between the active electrode and the solid electrolyte layer.

10. The PMC according to claim 1, wherein the solid electrolyte layer is a homogeneous mixture.

11. The PMC according to claim 1, wherein the solid electrolyte layer has a higher volume of low ion conductive material than high ion conductive material.

12. A method of forming a PMC comprising:
forming a first electrode;
forming a solid electrolyte layer that comprises high ion conductive material and low ion conductive material; and
forming a second electrode, wherein the second electrode is an active electrode.

13. The method according to claim 12 wherein the step of forming the solid electrolyte layer comprises a co-sputter deposition method.

14. The method according to claim 12, wherein the step of forming the solid electrolyte layer comprises chemical vapor deposition (CVD).

15. The method according to claim 12, wherein the step of forming the solid electrolyte layer comprises annealing deposited high ion conductive material and low ion conductive material.

16. The method according to claim 12 further comprising forming a sink layer after formation of the solid electrolyte layer.

17. The method according to claim 12, wherein the low ion conductive material is selected from the group consisting of: silicon dioxide (SiO₂), gadolinium oxide (Gd₂O₃), tungsten oxide (WOₓ), germanium sulfide (Ge₂S), and combinations thereof.

18. The method according to claim 12, wherein the high ion conductive material is selected from the group consisting of: silver sulfide (Ag₂S), silver iodide (AgI), copper sulfide (Cu₂S), copper iodide (CuI), copper tellurium (CuTe), silver selenide (Ag₂Se), silver tellurium (AgTe), and combinations thereof.

19. A nonvolatile memory unit comprising:
a resistive sense memory cell (RSM), the RSM comprising:
a first electrode;
a solid electrolyte layer comprising clusters of high ion conductive material dispersed in a low ion conductive material;
a second electrode; and
a sink layer
wherein the solid electrolyte layer is disposed between the first electrode and the second electrode
at least one word line; and
at least one bit line,
wherein the word line is orthogonal to the bit line and the RSM is operatively coupled to the word line and the bit line.

20. The nonvolatile memory unit according to claim 19 further comprising a semiconductor transistor, wherein the RSM is electrically coupled to the semiconductor transistor.
